(19) United States
(12) Patent Application Publication
(10) Pub. No.: US 2024/0255590 A1
(43) Pub. Date: Aug. 1, 2024

(54) WIRELESS COMMUNICATION SYSTEM, WIRELESS COMMUNICATION SYSTEM MANAGEMENT METHOD, WIRELESS COMMUNICATION DEVICE, AND CONTROL DEVICE

(71) Applicant: NIPPON TELEGRAPH AND TELEPHONE CORPORATION, Tokyo (JP)

(72) Inventors: Riku OMIYA, Musashino-shi, Tokyo (JP); Masashi IWABUCHI, Musashino-shi, Tokyo (JP); Tomoaki OGAWA, Musashino-shi, Tokyo (JP); Yasushi TAKATORI, Musashino-shi, Tokyo (JP)

(73) Assignee: NIPPON TELEGRAPH AND TELEPHONE CORPORATION, Tokyo (JP)

(21) Appl. No.: 18/293,775

(22) PCT Filed: Aug. 2, 2021
(86) PCT No.: PCT/JP2021/028649

§ 371 Date: Jan. 31, 2024

(51) Int. Cl. G01R 33/02; H04B 7/04

(52) U.S. Cl. CPC G01R 33/0206; H04B 7/04013

(57) ABSTRACT

A wireless communication system includes a terminal device and a control device that controls a wireless communication device that is used in wireless communication with the terminal device. The wireless communication device includes an electromagnet. The terminal device includes a magnetic sensor. The control device switches on and off the electromagnet. The control device acquires information on a first magnetic field detected by the magnetic sensor from the terminal device, when the electromagnet is off. The control device acquires information on a second magnetic field detected by the magnetic sensor from the terminal device, when the electromagnet is on. The control device estimates a direction from the wireless communication device to the terminal device based on a difference between the first magnetic field and the second magnetic field.

### TECHNICAL FIELD

The present disclosure relates to a technology for estimating a direction from a wireless communication device to a terminal device.

### BACKGROUND ART

In a wireless communication system including a terminal device and a wireless communication device, it is beneficial to recognize a direction from the wireless communication device to the terminal device (this direction will be hereinafter referred to as a “terminal direction”).

As an example of the wireless communication device, a reconfigurable intelligent surface (RIS: Reconfigurable Intelligent Surface) is considered. The reconfigurable intelligent surface includes a large number of reflective elements and is able to dynamically control reflection characteristics such as a direction of reflection. Using such a reconfigurable intelligent surface makes it possible to form a propagation path that bypasses an obstacle or to form a plurality of propagation paths for a single terminal device. This makes it possible to improve communication performance such as communication quality and the number of spatial multiplexes. To appropriately perform the wireless communication with the terminal device by utilizing the reconfigurable intelligent surface, it is necessary to recognize the terminal direction and to appropriately control a direction of reflection of radio waves by the reconfigurable intelligent surface.

Non Patent Literature 1 discloses a method for estimating a position of a wireless LAN terminal. According to this method, when a terminal belongs to an access point that uses a distributed antenna system, the access point estimates the position of the terminal.

Non Patent Literature 2 discloses a geomagnetic sensor.

### CITATION LIST

### Non Patent Literature

Non Patent Literature 1: Hosoda, et al., “Wireless LAN Terminal Position Estimation Method by Access Point Using Distributed Antenna System”, Journal of the Information Processing Society of Japan, Vol. 61, No. 1, pp. 3-15 (January 2020)

Non Patent Literature 2: Geomagnetic Sensor, Tech Web (https://techweb.rohm.co.jp/iot/knowledge/iot05/s-iot05/01-s-iot05/5055)

### SUMMARY OF INVENTION

### Technical Problem

An object of the present disclosure is to provide a technique capable of easily estimating a direction from a wireless communication device to a terminal device.

### Solution to Problem

A first aspect is directed to a wireless communication system.

The wireless communication system includes:
a terminal device; and
a control device configured to control a wireless communication device that is used in wireless communication with the terminal device.

The wireless communication device includes an electromagnet.

The terminal device includes a magnetic sensor.

The control device switches on and off the electromagnet.

The control device acquires information on a first magnetic field detected by the magnetic sensor from the terminal device, when the electromagnet is off.

The control device acquires information on a second magnetic field detected by the magnetic sensor from the terminal device, when the electromagnet is on.

The control device estimates a direction from the wireless communication device to the terminal device based on a difference between the first magnetic field and the second magnetic field.

A second aspect is directed to a wireless communication system management method for managing a wireless communication system. The wireless communication system includes a terminal device and a wireless communication device that is used in wireless communication with the terminal device.

The wireless communication system management method includes:
switching on and off an electromagnet included in the wireless communication device;
acquiring information on a first magnetic field detected by a magnetic sensor included in the terminal device, when the electromagnet is off;
acquiring information on a second magnetic field detected by the magnetic sensor, when the electromagnet is on; and
estimating a direction from the wireless communication device to the terminal device based on a difference between the first magnetic field and the second magnetic field.

A third aspect is directed to a wireless communication device that is used in wireless communication with a terminal device.

The wireless communication device includes a control device and an electromagnet.

The control device switches on and off the electromagnet.

The control device acquires, from the terminal device, information on a first magnetic field detected by a magnetic sensor included in the terminal device, when the electromagnet is off.

The control device acquires information on a second magnetic field detected by the magnetic sensor from the terminal device, when the electromagnet is on.

The control device estimates a direction from the wireless communication device to the terminal device based on a difference between the first magnetic field and the second magnetic field.

A fourth aspect is directed to a control device that controls a wireless communication device that is used in wireless communication with a terminal device.

The control device includes one or more processors.

The one or more processors switch on and off an electromagnet included in the wireless communication device.

The one or more processors acquire, from the terminal device, information on a first magnetic field detected by a magnetic sensor included in the terminal device, when the electromagnet is off.

The one or more processors acquire information on a second magnetic field detected by the magnetic sensor from the terminal device, when the electromagnet is on.

The one or more processors estimate a direction from the wireless communication device to the terminal device based on a difference between the first magnetic field and the second magnetic field.

### Advantageous Effects of Invention

According to the present disclosure, it is possible to easily estimate the direction from the wireless communication device to the terminal device by the use of the electromagnet of the wireless communication device and the magnetic sensor of the terminal device.

### BRIEF DESCRIPTION OF DRAWINGS

FIG. 1 is a conceptual diagram illustrating an example of a wireless communication system according to an embodiment of the present disclosure.

FIG. 2 is a conceptual diagram for explaining a terminal direction estimation process according to an embodiment of the present disclosure.

FIG. 3 is a flowchart showing processing related to the terminal direction estimation process according to an embodiment of the present disclosure.

FIG. 4 is a block diagram illustrating a configuration example of a wireless communication device according to an embodiment of the present disclosure.

FIG. 5 is a block diagram illustrating a configuration example of a terminal device according to an embodiment of the present disclosure.

FIG. 6 is a flowchart showing an example of processing performed by a control device according to an embodiment of the present disclosure.

FIG. 7 is a block diagram illustrating a modification example of the embodiment of the present disclosure.

### DESCRIPTION OF EMBODIMENTS

Embodiments of the present disclosure will be described with reference to the accompanying drawings.

### 1. Wireless Communication System

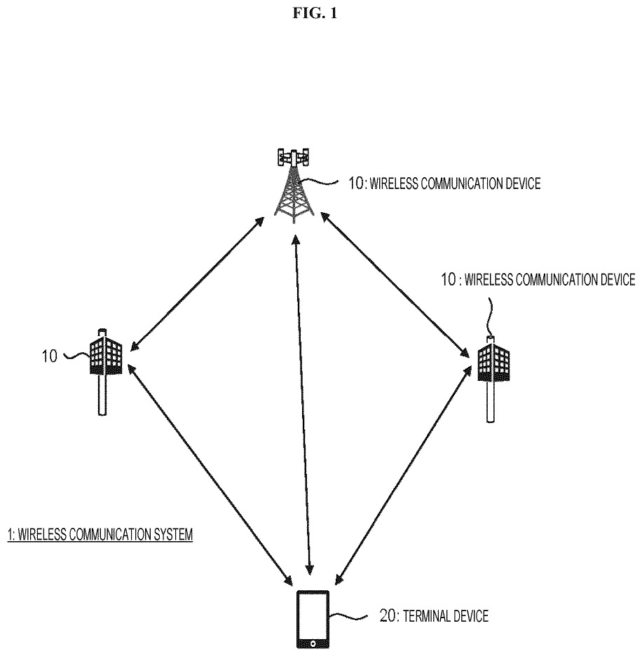

FIG. 1 is a conceptual diagram illustrating an example of a wireless communication system 1 according to the present embodiment. The wireless communication system 1 includes a wireless communication device 10 and a terminal device 20. Examples of the terminal device 20 include a smartphone and a PC.

The wireless communication device 10 is used for wireless communication with the terminal device 20. Examples of the wireless communication device 10 include a base station, an access point, a repeater, and the like. The base station and the access point may perform beamforming. The repeater relays signal communication between another wireless communication device 10 and the terminal device 20. Examples of the repeater include a repeater (smart repeater) capable of beam control, a reconfigurable intelligent surface (RIS: Reconfigurable Intelligent Surface) that reflects radio waves, and the like.

The reconfigurable intelligent surface includes a large number of reflective elements and is able to dynamically control reflection characteristics such as a direction of reflection. For example, the reconfigurable intelligent surface is a meta-surface reflector. Using such a reconfigurable intelligent surface makes it possible to form a propagation path that bypasses an obstacle or to form a plurality of propagation paths for a single terminal device 20. This makes it possible to improve communication performance such as communication quality and the number of spatial multiplexes.

In the wireless communication system 1 including the wireless communication device 10 and the terminal device 20, it is beneficial to recognize a direction from the wireless communication device 10 to the terminal device 20 (this direction will be hereinafter referred to as a “terminal direction D”). For example, to appropriately perform the wireless communication with the terminal device 20 by utilizing a reconfigurable intelligent surface, it is necessary to recognize the terminal direction D and to appropriately control a direction of reflection of radio waves by the reconfigurable intelligent surface. Moreover, the terminal direction D is also beneficial in beamforming in the wireless communication device 10.

Hereinafter, a “terminal direction estimation process” for estimating the terminal direction D from the wireless communication device 10 to the terminal device 20 will be described.

### 2. Terminal Direction Estimation Process

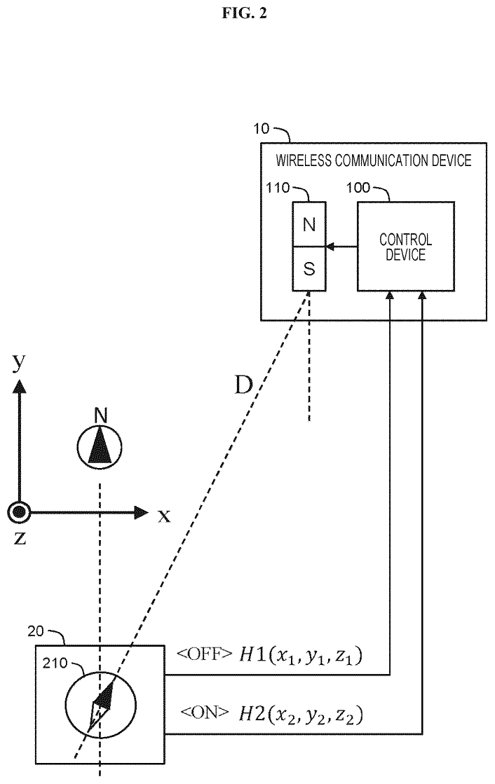

FIG. 2 is a conceptual diagram for explaining the terminal direction estimation process according to the present embodiment.

The wireless communication device 10 according to the present embodiment includes a control device 100 and an electromagnet 110. The control device 100 controls the wireless communication device 10. In addition, the control device 100 switches on and off the electromagnet 110. The electromagnet 110 generates a magnetic field when switched on by the control device 100. Further, the control device 100 can communicate with the terminal device 20. As a modification example, the control device 100 may be disposed outside the wireless communication device 10 to extemally control the wireless communication device 10 and the electromagnet 110.

Meanwhile, the terminal device 20 according to the present embodiment includes a magnetic sensor 210 that detects a magnetic field. A magnetic field is defined in a predetermined coordinate system (x, y, z). For example, the x-axis is parallel to latitude lines, the y-axis is parallel to meridian lines, and the z-axis is a vertical axis. The magnetic field detected by the magnetic sensor 210 has an x-component, a y-component, and a z-component.

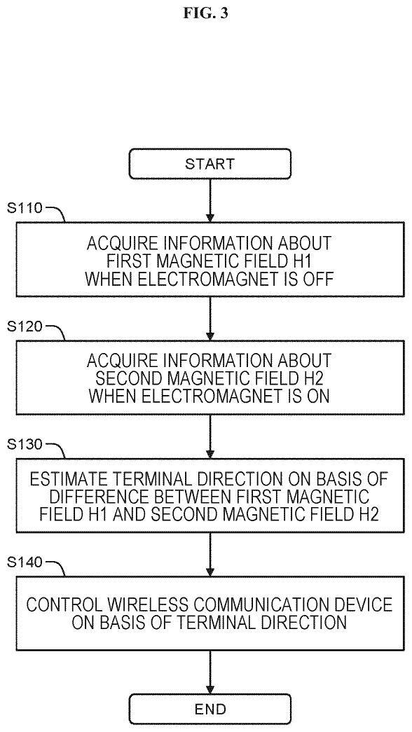

FIG. 3 is a flowchart showing processing related to the terminal direction estimation process.

In Step S110, the control device 100 turns off the electromagnet 110 of the wireless communication device 10. A magnetic field detected by the magnetic sensor 210 of the terminal device 20 at this point of time is hereinafter referred to as a “first magnetic field H1 (x1, y1, z1)”. The first magnetic field H1 corresponds to a geomagnetic field at a position of the terminal device 20. The control device 100 acquires information on the detected first magnetic field H1 from the terminal device 20.

In Step S120, the control device 100 turns on the electromagnet 110 of the wireless communication device 10. The electromagnet 110 generates a magnetic field in the surroundings. The magnetic field caused by the electromagnet 110 and generated at the position of the terminal device 20 is hereinafter referred to as an “electromagnet-induced magnetic field He”. Further, a magnetic field detected by the magnetic sensor 210 of the terminal device 20 at this point of time is hereinafter referred to as a “second magnetic field H2 (x2, y2, z2)”. The second magnetic field H2 is expressed as a vector sum of the first magnetic field H1 and the electromagnet-induced magnetic field He (i.e., H2=H1+He). The control device 100 acquires information on the detected second magnetic field H2 from the terminal device 20.

It should be noted that an electric current of the electromagnet 110 is preferably controlled so that the electromagnet-induced magnetic field He stronger than the geomagnetic field is generated at the position of the terminal device 20.

It should be noted that the order of Steps S110 and S120 may be reversed.

In Step S130, the control device 100 estimates the terminal direction D based on a comparison between the first magnetic field H1 and the second magnetic field H2. As described above, the second magnetic field H2 is expressed as the vector sum of the first magnetic field H1 and the electromagnet-induced magnetic field He (i.e., H2=H1+He). Accordingly, the electromagnet-induced magnetic field He at the position of the terminal device 20 is given by a difference between the second magnetic field H2 and the first magnetic field H1 (i.e., He=H2−H1). The control device 100 estimates the terminal direction D based on the electromagnet-induced magnetic field He that is the difference between the second magnetic field H2 and the first magnetic field H1.

For example, as illustrated in FIG. 2, in a case where an angle between an installation direction (i.e., a direction from a north pole to a south pole) of the electromagnet 110 and the terminal direction D is relatively small, a direction of the electromagnet-induced magnetic field He at the position of the terminal device 20 is close to parallel to the terminal direction D. For example, the wireless communication device 10 is a reconfigurable intelligent surface, and the electromagnet 110 is installed so that the installation direction thereof is substantially orthogonal to a reflecting surface of the reconfigurable intelligent surface. In this case, an angle between the terminal direction D toward the terminal device 20 receiving radio waves reflected by the reconfigurable intelligent surface and the installation direction of the electromagnet 110 is relatively small. Accordingly, a direction of the electromagnet-induced magnetic field He at the position of the terminal device 20 is close to parallel to the terminal direction D. For example, the control device 100 approximately estimates that the terminal direction D is parallel to the direction of the electromagnet-induced magnetic field He. In this case, an azimuth angle φ and an zenith angle θ of the terminal direction D are expressed by the following Equations (1) and (2), respectively.

$$\begin{matrix}[ Equation 1 ] & \\ φ = arctan ( \frac{{y}_{2} - {y}_{1}}{{x}_{2} - {x}_{1}} ) & ( 1 )\end{matrix}$$

$$\begin{matrix}[ Equation 2 ] & \\ θ = arccos ( \frac{{z}_{2} - {z}_{1}}{\sqrt{{( {x}_{2} - {x}_{1} )}^{2} + {( {y}_{2} - {y}_{1} )}^{2} + {( {z}_{2} - {z}_{1} )}^{2}}} ) & ( 2 )\end{matrix}$$

In Step S140, the control device 100 controls the wireless communication device 10 on the basis of the estimated terminal direction D. For example, in a case where the wireless communication device 10 is a reconfigurable intelligent surface, the control device 100 controls a direction of reflection of radio waves by the reconfigurable intelligent surface, on the basis of the estimated terminal direction D. That is, the control device 100 controls the direction of reflection so that radio waves incident on the reconfigurable intelligent surface are reflected in the terminal direction D. As another example, the control device 100 may control beamforming in the wireless communication device 10 on the basis of the estimated terminal direction D.

As described above, according to the present embodiment, it is possible to easily estimate the terminal direction D from the wireless communication device 10 to the terminal device 20 by the use of the electromagnet 110 of the wireless communication device 10 and the magnetic sensor 210 of the terminal device 20.

It can be also said that the present embodiment provides a wireless communication system management method that includes estimation of the terminal direction D and control of the wireless communication device 10.

### 3. Configuration Examples and Processing Examples

### 3-1. Configuration Example of Wireless Communication Device

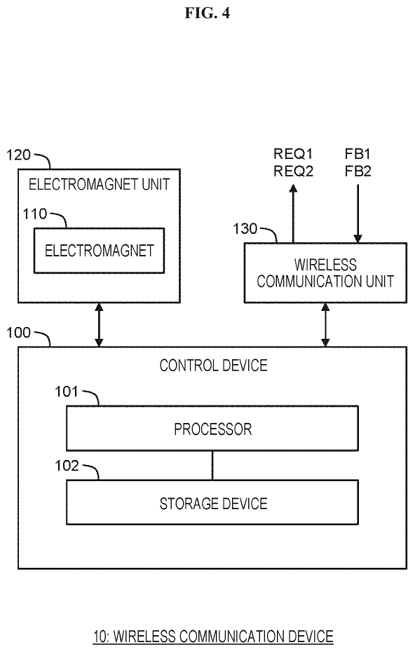

FIG. 4 is a block diagram illustrating a configuration example of the wireless communication device 10. The wireless communication device 10 includes the control device 100, an electromagnet unit 120, and a wireless communication unit 130.

The control device 100 controls the wireless communication device 10. For example, the control device 100 includes one or more processors 101 (hereinafter simply referred to as a “processor 101”) and one or more storage devices 102 (hereinafter simply referred to as a “storage device 102”). The processor 101 executes a variety of information processing. For example, the processor 101 includes a central processing unit (CPU). The storage device 102 stores a variety of information necessary for the processing by the processor 101. Examples of the storage device 102 include a volatile memory, a nonvolatile memory, a hard disk drive (HDD), a solid state drive (SSD), and the like. The functions of the control device 100 are implemented by the processor 101 executing a control program that is a computer program. The control program is stored in the storage device 102. The control program may be recorded on a non-transitory computer-readable recording medium. The control program may be provided via a network. In yet another example, the control device 100 may be realized by hardware such as an application specific integrated circuit (ASIC), a programmable logic device (PLD), a field programmable gate array (FPGA), and the like.

The electromagnet unit 120 includes the electromagnet 110, a current supply unit that supplies current to the electromagnet 110, a switch that turns on and off the current supply, and the like. The current supply in the electromagnet unit 120, that is, switching on and off the electromagnet 110 is controlled by the control device 100 (the processor 101).

The wireless communication unit 130 performs wireless communication with the terminal device 20. For example, the wireless communication unit 130 includes an antenna and a transceiver. In another example, the wireless communication unit 130 may include a plurality of reflective elements. The wireless communication unit 130 is controlled by the control device 100 (the processor 101). For example, the control device 100 controls the radio wave reflection direction on the basis of the terminal direction D.

### 3-2. Configuration Example of Terminal Device

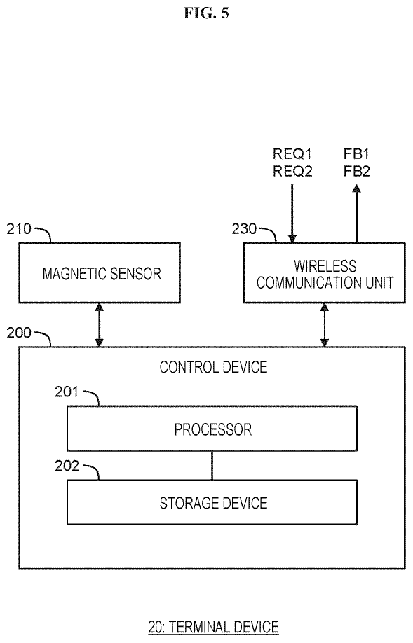

FIG. 5 is a block diagram illustrating a configuration example of the terminal device 20. The terminal device 20 includes a control device 200, the magnetic sensor 210, and a wireless communication unit 230.

The control device 200 controls the terminal device 20. For example, the control device 200 includes one or more processors 201 (hereinafter simply referred to as a “processor 201”) and one or more storage devices 202 (hereinafter simply referred to as a “storage device 202”). The processor 201 executes a variety of information processing. For example, the processor 201 includes a CPU. The storage device 202 stores a variety of information necessary for the processing by the processor 201. Examples of the storage device 202 include a volatile memory, a nonvolatile memory, an HDD, an SSD, and the like. The functions of the control device 200 are implemented by the processor 201 executing a control program that is a computer program. The control program is stored in the storage device 202. The control program may be recorded on a non-transitory computer-readable recording medium.

The magnetic sensor 210 detects a magnetic field. Examples of the magnetic sensor 210 include a Hall sensor, a magneto-resistance (MR) sensor, a magneto-impedance (MI) sensor, and the like (see Non Patent Literature 2).

The wireless communication unit 230 performs wireless communication with the wireless communication device 10 (the control device 100). For example, the wireless communication unit 230 includes an antenna and a transceiver. The wireless communication unit 230 is controlled by the control device 200 (the processor 201).

### 3-3. Example of Processing Flow

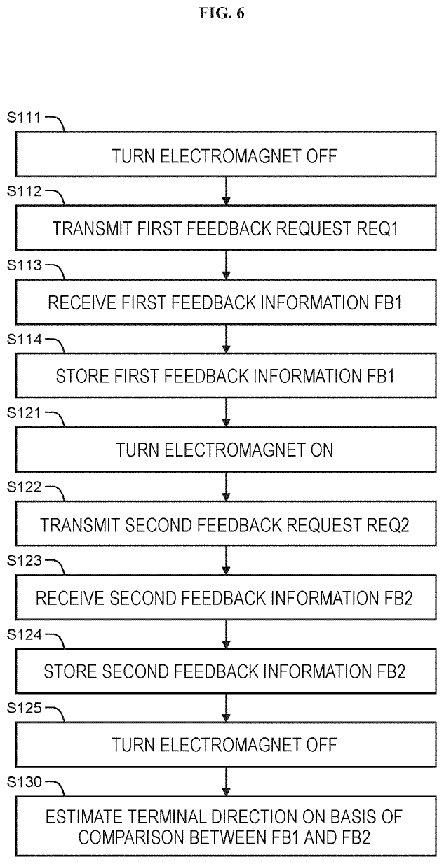

FIG. 6 is a flowchart illustrating an example of the processing performed by the control device 100 (the processor 101).

In Step S111, the control device 100 turns off the electromagnet 110.

In Step S112 after Step S111, the control device 100 transmits a first feedback request REQ1 to the terminal device 20 via the wireless communication unit 130.

The control device 200 of the terminal device 20 receives the first feedback request REQ1 via the wireless communication unit 230. The magnetic field detected by the magnetic sensor 210 at this point of time is the first magnetic field H1. In response to the first feedback request REQ1, the control device 200 transmits first feedback information FB1 indicating the first magnetic field H1 to the control device 100 via the wireless communication unit 230.

In Step S113, the control device 100 receives the first feedback information FB1 from the terminal device 20 via the wireless communication unit 130.

In Step S114, the control device 100 stores the received first feedback information FB1 in the storage device 102.

It should be noted that Steps S111 to S114 described above correspond to Step S110 shown in FIG. 3.

In Step S121, the control device 100 turns on the electromagnet 110.

In Step S122 after Step S121, the control device 100 transmits a second feedback request REQ2 to the terminal device 20 via the wireless communication unit 130.

The control device 200 of the terminal device 20 receives the second feedback request REQ2 via the wireless communication unit 230. The magnetic field detected by the magnetic sensor 210 at this point of time is the second magnetic field H2. In response to the second feedback request REQ2, the control device 200 transmits second feedback information FB2 indicating the second magnetic field H2 to the control device 100 via the wireless communication unit 230.

In Step S123, the control device 100 receives the second feedback information FB2 from the terminal device 20 via the wireless communication unit 130.

In Step S124, the control device 100 stores the received second feedback information FB2 in the storage device 102.

In Step S125, the control device 100 turns off the electromagnet 110.

It should be noted that Steps S121 to S125 described above correspond to Step S120 shown in FIG. 3.

In Step S130, the control device 100 estimates the terminal direction D based on a comparison between the first feedback information FB1 and the second feedback information FB2 stored in the storage device 102. More specifically, the control device 100 estimates the terminal direction D on the basis of the difference between the second magnetic field H2 indicated by the second feedback information FB2 and the first magnetic field H1 indicated by the first feedback information FB1. Information on the estimated terminal direction D is stored in the storage device 102, and is used in controlling the wireless communication device 10.

### 3-4. Modification Example

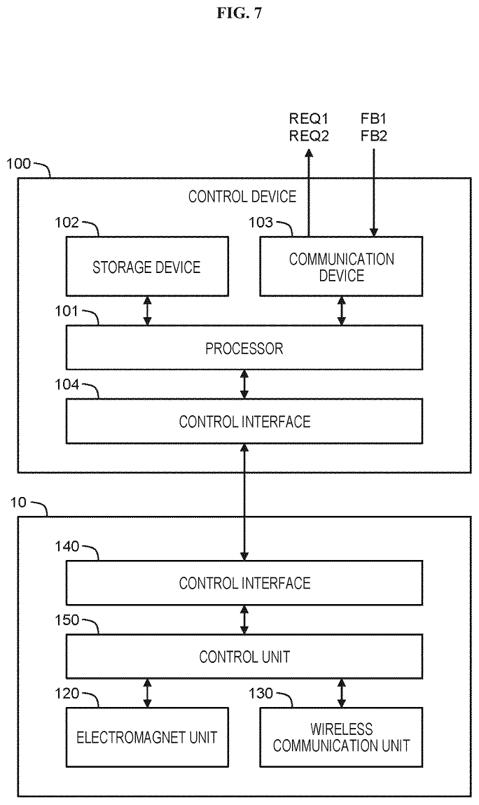

FIG. 7 is a block diagram illustrating a modification example. In the modification example, the control device 100 is disposed outside the wireless communication device 10, and externally controls the wireless communication device 10 and the electromagnet 110.

The control device 100 includes the processor 101, the storage device 102, a communication device 103, and a control interface 104.

The communication device 103 communicates with the terminal device 20. The processor 101 transmits the feedback requests REQ1 and REQ2 to the terminal device 20 via the communication device 103. Moreover, the processor 101 receives the feedback information FB1 and FB2 from the terminal device 20 via the communication device 103.

The control interface 104 is an interface for controlling the wireless communication device 10. The processor 101 transmits control information for controlling the wireless communication device 10, to the wireless communication device 10 via the control interface 104. For example, the control information includes information instructing to switch on and off the electromagnet 110. By transmitting such the control information to the wireless communication device 10, the processor 101 can switch on and off the electromagnet 110. In another example, the control information may include the terminal direction D estimated by the processor 101.

The wireless communication device 10 includes the electromagnet unit 120, the wireless communication unit 130, a control interface 140, and a control unit 150.

The control unit 150 receives the control information from the control device 100 via the control interface 140. The control unit 150 switches on and off the electromagnet 110 in accordance with the control information. Moreover, the control unit 150 controls the wireless communication unit 130. For example, the control unit 150 controls the radio wave reflection direction on the basis of the terminal direction D.

### REFERENCE SIGNS LIST

1 wireless communication system
10 wireless communication device
20 terminal device
100 control device
101 processor
102 storage device
110 electromagnet
210 magnetic sensor
H1 first magnetic field
H2 second magnetic field

1. A wireless communication system comprising:
a terminal device; and
a controller configured to control a wireless communication device that is used in wireless communication with the terminal device, wherein
the wireless communication device includes an electromagnet,
the terminal device includes a magnetic sensor, and
the controller is configured to:
switch on and off the electromagnet;
acquire information on a first magnetic field detected by the magnetic sensor from the terminal device, when the electromagnet is off;
acquire information on a second magnetic field detected by the magnetic sensor from the terminal device, when the electromagnet is on; and
estimate a direction from the wireless communication device to the terminal device based on a difference between the first magnetic field and the second magnetic field.

2. The wireless communication system according to claim 1, wherein
the controller is configured to transmit a first feedback request to the terminal device after switching off the electromagnet,
the terminal device is configured to transmit first feedback information indicating the first magnetic field detected by the magnetic sensor to the controller in response to the first feedback request,
the controller is configured to transmit a second feedback request to the terminal device after switching on the electromagnet, and
the terminal device is configured to transmit second feedback information indicating the second magnetic field detected by the magnetic sensor to the controller in response to the second feedback request.

3. The wireless communication system according to claim 1, wherein
the wireless communication device is a reconfigurable intelligent surface.

4. The wireless communication system according to claim 3, wherein
the controller is configured to control a direction of reflection of radio waves by the reconfigurable intelligent surface based on the direction from the reconfigurable intelligent surface to the terminal device.

5. The wireless communication system according to claim 3, wherein
the electromagnet is installed so that a direction from a north pole to a south pole of the electromagnet is orthogonal to a reflecting surface of the reconfigurable intelligent surface.

6. A wireless communication system management method for managing a wireless communication system including a terminal device and a wireless communication device that is used in wireless communication with the terminal device,
the wireless communication system management method comprising:
switching on and off an electromagnet included in the wireless communication device;
acquiring information on a first magnetic field detected by a magnetic sensor included in the terminal device, when the electromagnet is off;
acquiring information on a second magnetic field detected by the magnetic sensor, when the electromagnet is on; and
estimating a direction from the wireless communication device to the terminal device based on a difference between the first magnetic field and the second magnetic field.

7. (canceled)

8. A controller that controls a wireless communication device that is used in wireless communication with a terminal device,
the controller comprising processing circuitry, wherein
the processing circuitry is configured to:
switch on and off an electromagnet included in the wireless communication device;
acquire, from the terminal device, information on a first magnetic field detected by a magnetic sensor included in the terminal device, when the electromagnet is off;
acquire information on a second magnetic field detected by the magnetic sensor from the terminal device, when the electromagnet is on; and
estimate a direction from the wireless communication device to the terminal device based on a difference between the first magnetic field and the second magnetic field.
